(19) United States
(12) Patent Application Publication
(10) Pub. No.: US 2007/0082434 A1
(43) Pub. Date: Apr. 12, 2007

(54) Manufacturing of thin film transistor array panel

(75) Inventors: Yang-Ho Bae, Suwon-si (KR); Chang-Oh Jeong, Suwon-si (KR); Je-Hun Lee, Seoul (KR); Beom-Seok Cho, Seoul (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/540,131

(22) Filed: Sep. 29, 2006

(30) Foreign Application Priority Data
Oct. 7, 2005 (KR) 10-2005-0094423

(51) Int. Cl. H01L 21/84; H01L 21/00

(52) U.S. Cl. 438/149; 438/151

(57) ABSTRACT

The present invention relates to a manufacturing method of a thin film transistor array panel. the method includes forming a gate line including a gate electrode on a substrate, forming a first insulating layer on the gate line, forming a semiconductor layer on the first insulating layer, forming an ohmic contact on the semiconductor layer, forming a data line including a source electrode and a drain electrode on the ohmic contact, depositing a second insulating layer, forming a first photoresist on the second insulating layer, etching the second insulating layer and the first insulating layer using the first photoresist as an etching mask to expose a portion of the drain electrode and a portion of the substrate, forming a pixel electrode connected to an exposed portion of the drain electrode using selective deposition, and removing the first photoresist.

### CROSS-REFERENCE TO RELATED APPLICATION

This application claims priority to and the benefit of Korean Patent Application No. 10-2005-0094423 filed in the Korean Intellectual Property Office on Oct. 7, 2005, the contents of which are incorporated herein by reference.

### FIELD OF THE INVENTION

The present invention relates to manufacturing of a thin film transistor array panel.

### DESCRIPTION OF THE RELATED ART

Active matrix display devices such as a liquid crystal display (LCD) and an organic light emitting display (OLED) include a plurality of pixels arranged in a matrix. The pixels include switching elements such as thin film transistors having a gate electrode, a source electrode, and a drain electrode. Conventionally, photolithography and etching steps are used repeatedly to pattern multiple thin film layers to form the TFT array panel. The photolithography steps increase manufacturing cost and time. Therefore, it would be advantageous to reduce the number of photolithography steps.

### SUMMARY OF THE INVENTION

The method of the present invention includes forming a gate line comprising a gate electrode on a substrate, forming a first insulating layer on the gate line, forming a semiconductor layer on the first insulating layer, forming an ohmic contact on the semiconductor layer, forming a data line comprising a source electrode and a drain electrode on the ohmic contact, depositing a second insulating layer, forming a first photoresist on the second insulating layer, etching the second insulating layer and the first insulating layer using the first photoresist as an etching mask to expose a portion of the drain electrode and a portion of the substrate, forming a pixel electrode connected to an exposed portion of the drain electrode using selective deposition, advantageously MOCVD (metal organic chemical vapor deposition), and removing the first photoresist.

The MOCVD may be performed under about 130° C. or less.

The first photoresist may be hydrophobic and may include at least one hydrocarbon.

The first photoresist may be octadecyl trichloro silane (OTS).

The first photoresist may be hydrophilic and the method may further comprise treating the surface of the first photoresist to make the surface of the first photoreist hydrophoblic and the surface of the first photoresist may be treated by the octadecyl trichloro silane.

The exposure of the drain electrode and the substrate may include exposing a portion of the data line and a portion of the gate line.

The first photoreisist may be formed by a photomask comprising a light blocking area and a light transmitting area.

The first photoreisist may be formed by a photomask comprising a light blocking area, a light transmitting area, and a translucent area, and the method may further comprise forming a second photoreist by changing the first photoresist.

The drain electrode may comprise an expansion, and the translucent area may face near an edge of the expansion.

The formation of the semiconductor layer and the formation of the data line and the drain electrode may include sequentially depositing the gate insulating layer, an intrinsic amorphous silicon layer, an extrinsic amorphous silicon layer, and a data conductive layer on the gate line, forming the second photoresist having position-dependent thickness on the data conductive layer, and selectively etching the data conductive layer, the extrinsic amorphous silicon layer, and the intrinsic amorphous silicon layer using the second photoresist as a mask to form the data line, the drain electrode, and the ohmic contact.

The second photoresist may be formed by a photo mask comprising a light blocking area, a translucent area, and a light transmitting area.

### BRIEF DESCRIPTION OF THE DRAWINGS

The present invention may become more apparent from a reading of the ensuing description together with the drawing, in which:

FIG. 1 is a layout view of a TFT array lower panel according to an embodiment of the present invention.

FIGS. 2A and 2B are sectional views of the TFT array panel shown in FIG. 1 taken along the lines IIA-IIA and IIB-IIB, respectively.

FIGS. 3, 6, and 9 are layout views of a TFT array panel shown in FIGS. 1-2B in intermediate steps of a manufacturing method thereof according to an embodiment of the present invention.

FIGS. 4A and 4B are sectional views of the TFT array panel shown in FIG. 3 taken along the lines IVA-IVA and IVB-IVB, respectively.

FIGS. 5A and 5B illustrate the step following the step shown in FIGS. 4A and 4B.

FIG. 7A are sectional views of the TFT array panel shown in FIG. 6 taken along the lines VIIA-VIIA and VIIB-VIIB, respectively.

FIGS. 8A and 8B illustrate the step following the step shown in FIGS. 7A and 7B.

FIGS. 9A and 9B illustrate the step following the step shown in FIGS. 8A and 8B.

FIGS. 11A and 11B are sectional views of the TFT array panel shown in FIG. 10 taken along the lines XIA-XIA and XIB-XIB, respectively.

FIGS. 12A and 12B illustrate the step following the step shown in FIGS. 11A and 11B.

### DETAILED DESCRIPTION OF THE EMBODIMENTS

In the drawings, the thickness of layers and regions are exaggerated for clarity. Like numerals refer to like elements throughout. It will be understood that when an element such as a layer, region, or substrate is referred to as being “on” another element, it can be directly on the other element or intervening elements may also be present. In contrast, when an element is referred to as being “directly on” another element, there are no intervening elements present.

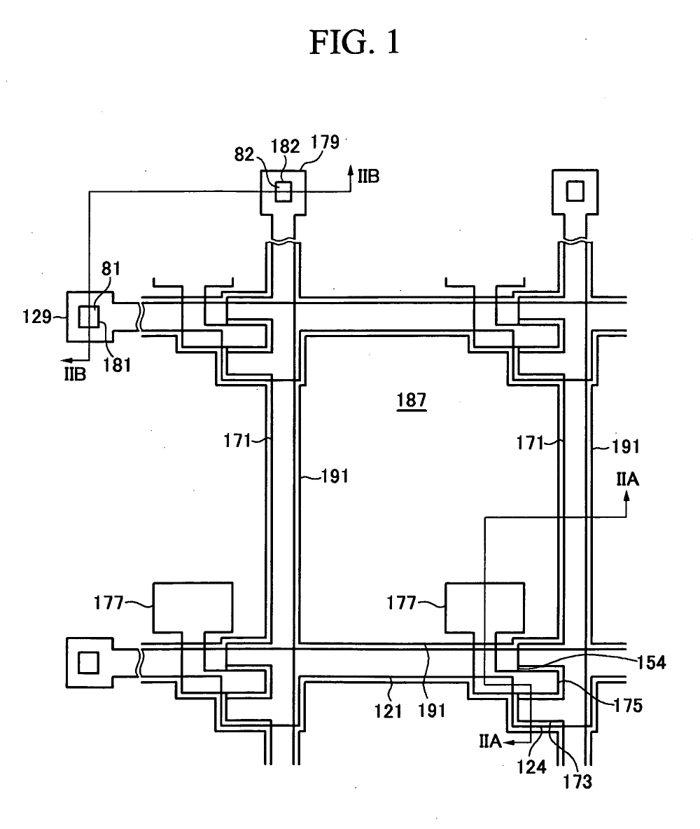

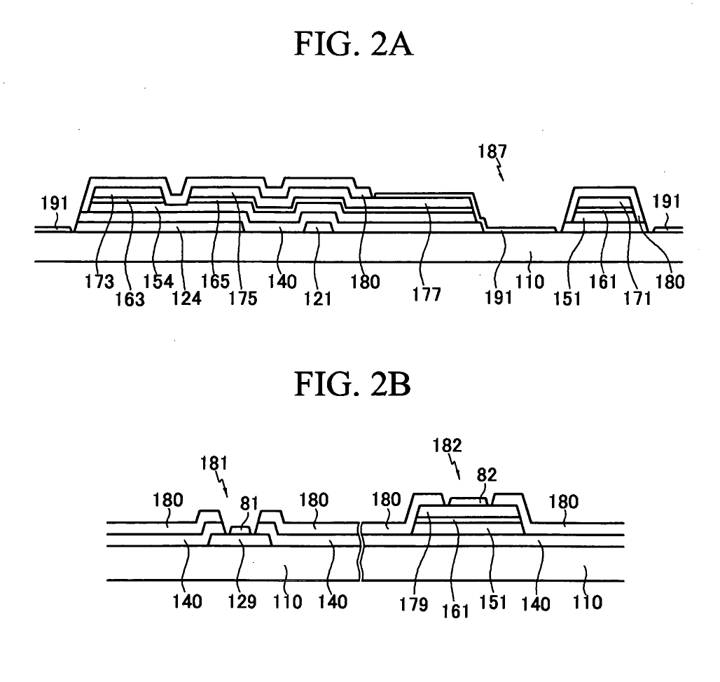

A TFT array panel according to an embodiment of the present invention will be described in detail with reference to FIGS. 1, 2A, and 2B.

FIG. 1 is a layout view of a TFT array lower panel according to an embodiment of the present invention, FIG. 2A is a sectional view of the TFT array panel shown in FIG. 1 taken along the line IIA-IIA, and FIG. 2B is a sectional view of the TFT array panel shown in FIG. 1 taken along the lines IIB-IIB.

Referring to FIGS. 1 to 2B, a plurality of gate lines 121 are formed on an insulating substrate 110 that is made of a material such as transparent glass or plastic. Gate lines 121 transmit gate signals and extend substantially in a transverse direction. Each of gate lines 121 includes a plurality of gate electrodes 124 projecting upward and end portions 129 having a large area for contact with another layer or an external driving circuit. A gate driving circuit (not shown) for generating the gate signals may be mounted on a flexible printed circuit (FPC) film (not shown), which may be attached to, directly mounted on, or integrated onto substrate 110. Gate lines 121 may extend to be connected to a driving circuit that may also be integrated onto the substrate 110.

Gate lines 121 are preferably made of an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, and Ti. However, they may have a multi-layered structure including two conductive films (not shown) having different physical characteristics. One of the two films is preferably made of a low resistivity metal such as an Al-containing metal, an Ag-containing metal, and a Cu-containing metal for reducing signal delay or voltage drop. The other film is preferably made of a material such as a Mo-containing metal, Cr, Ta, or Ti, which have good physical, chemical, and electrical contact characteristics with other materials such as indium tin oxide (ITO) and indium zinc oxide (IZO). Good examples of the combination of the two films are a lower Cr film and an upper Al (alloy) film and a lower Al (alloy) film and an upper Mo (alloy) film. However, gate lines 121 may be made of various metals or conductors.

The lateral sides of gate lines 121 are inclined relative to a surface of the substrate 110, and the inclination angle thereof ranges from about 30 to 80 degrees.

A gate insulating layer 140 preferably made of silicon nitride (SiNx) or silicon oxide (SiOx) is formed on gate lines 121.

A plurality of semiconductor stripes 151, preferably made of hydrogenated amorphous silicon (abbreviated to “a-Si”) or polysilicon, are formed on the gate insulating layer 140. Semiconductor stripes 151 extend substantially in the longitudinal direction. Each of semiconductor stripes 151 includes a plurality of projections 154 branched out toward gate electrodes 124.

A plurality of ohmic contact stripes and islands 161 and 165 are formed on semiconductor stripes 151. The ohmic contact stripes and islands 161 and 165 are preferably made of n+hydrogenated a-Si heavily doped with an N-type impurity such as phosphorous, or they may be made of silicide. Each ohmic contact stripe 161 includes a plurality of projections 163. Projections 163 and the ohmic contact islands 165 are located in pairs on projections 154 of semiconductor stripes 151. The lateral sides of semiconductor stripes 151 and the ohmic contacts 161 and 165 are inclined relative to the surface of the substrate 110, and the inclination angles thereof are preferably in a range of about 30 to 80 degrees.

A plurality of data lines 171 and a plurality of drain electrodes 175 are formed on the ohmic contacts 161 and 165 and gate insulating layer 140.

Data lines 171 transmit data signals and extend substantially in the longitudinal direction to intersect gate lines 121. Each data line 171 includes a plurality of source electrodes 173 projecting toward the gate electrodes, and an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated onto the substrate 110. Data lines 171 may extend to be connected to a driving circuit that may be integrated onto the substrate 110.

Drain electrodes 175 are separated from data lines 171 and disposed opposite source electrodes 173 with respect to gate electrodes 124. Each of drain electrodes 175 includes a wide end portion, that is, an expansion 177 and a narrow end portion. The narrow end portion is partly enclosed by a source electrode 173.

A gate electrode 124, a source electrode 173, and a drain electrode 175 along with a projection 154 of a semiconductor stripe 151 form a TFT having a channel formed in projection 154 disposed between the source electrode 173 and the drain electrode 175.

Data lines 171 and drain electrodes 175 are preferably made of a refractory metal such as Cr, Mo, Ta, Ti, or alloys thereof. However, they may have a multilayered structure including a refractory metal film (not shown) and a low resistivity film (not shown). Good examples of the multi-layered structure are a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, data lines 171 and the drain electrodes 175 may be made of various metals or conductors.

Data lines 171 and the drain electrodes 175 have inclined edge profiles, and the inclination angles thereof range from about 30 to 80 degrees.

Ohmic contacts 161 and 165 are interposed only between the underlying semiconductor stripes 151 and the overlying conductors 171 and 175 thereon, and they reduce the contact resistance therebetween.

Semiconductor stripes 151 have almost the same planar shapes as data lines 171 and the drain electrodes 175 as well as the underlying ohmic contacts 161 and 165. However, semiconductor stripes 151 include some exposed portions, which are not covered with data lines 171 and the drain electrodes 175, such as portions located between the source electrodes 173 and the drain electrodes 175.

A passivation layer 180 is formed on gate lines 121, data lines 171, the drain electrodes 175, and the exposed portions 154 of semiconductor stripes 151.

The passivation layer 180 is made of an inorganic insulator such as silicon nitride and silicon oxide. However, the passivation layer 180 may be made of an organic insulator having photosensitivity and a dielectric constant lower than 4.0. The passivation layer 180 may have a double-layered structure including a lower inorganic film and an upper organic film, to have a good insulating characteristic of the organic film and to protect the exposed semiconductors 154.

Alternatively, the passivation layer 180 may be formed near the edges of the expansions of the drain electrode 175.

The passivation layer 180 has a plurality of contact holes 182 exposing the end portions 179 of data lines 171. The passivation layer 180 also has a plurality of openings 187 exposing portions of the drain electrodes 175 of areas enclosed by gate lines 121 and data lines 171, and exposing the substrate 140 along with the gate insulating layer 140. The passivation layer 180 and the gate insulating layer 140 have a plurality of contact holes 181 exposing end portions 129 of gate lines 121.

A plurality of pixel electrode 191 and a plurality of contact assistants 81 and 82 are formed on the exposed portions of the drain electrode 175, the exposed portion of the substrate 110, and the exposed end portions 129 and 179 of the gate line 121 and data line 171. They are preferably made of a transparent conductor such as ITO or IZO, or a reflective conductor such as Ag, Al, Cr, or alloys thereof.

Pixel electrodes 191 and the contact assistants 81 and 82 are formed by a selective deposition manner such as MOCVD (metal organic chemical vapor deposition), or by ELP (electroless plating).

Pixel electrodes 191 are physically and electrically connected to the drain electrodes 175 through the openings 187 such that pixel electrodes 191 receive data voltages from the drain electrodes 175. Pixel electrodes 191 supplied with the data voltages generate electric fields in cooperation with a common electrode (not shown) of the opposing display panel supplied with a common voltage, which determine the orientations of liquid crystal molecules (not shown) of a liquid crystal layer (not shown) disposed between the two panels. Thereby the polarization of light passing through the liquid crystal layer is varied by the orientations of the liquid crystal molecules.

Concerning an LCD, a pixel electrode 191 and a common electrode form a capacitor referred to as “liquid crystal capacitor,” which stores applied voltages after the TFT turns off. An additional capacitor called a “storage capacitor,” which is connected in parallel to the liquid crystal capacitor, is provided for enhancing the voltage storing capacity. The storage capacitors are implemented by overlapping pixel electrodes 191 with previous gate lines 121 adjacent thereto or separate signal lines. The capacitances of the storage capacitors, i.e., the storage capacitances, may be increased by providing projections (not shown) at gate lines 121 for increasing overlapping areas and by providing storage capacitor conductors (not shown), which are connected to pixel electrodes 191 and overlap the projections of gate lines 121, under pixel electrodes 191 for decreasing the distance between the terminals.

The contact assistants 81 and 82 are connected to the end portions 129 of gate lines 121 and the end portions 179 of data lines 171 through the contact holes 181 and 182, respectively. The contact assistants 81 and 82 protect the end portions 129 and 179 and enhance the adhesion between the end portions 129 and 179 and external devices.

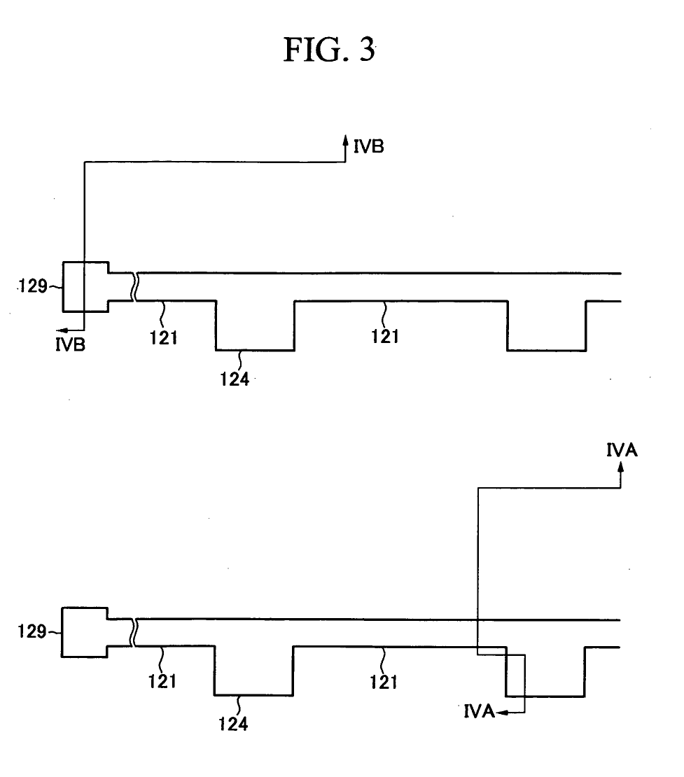

Now, a method of manufacturing the TFT array panel shown in FIGS. 1-2B will be described in detail with reference to FIGS. 3-12B as well as FIGS. 1-2B.

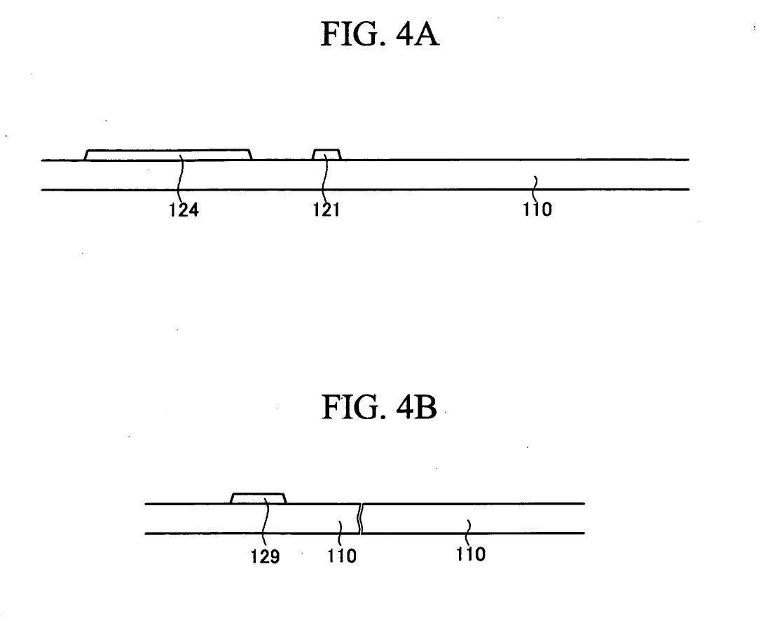

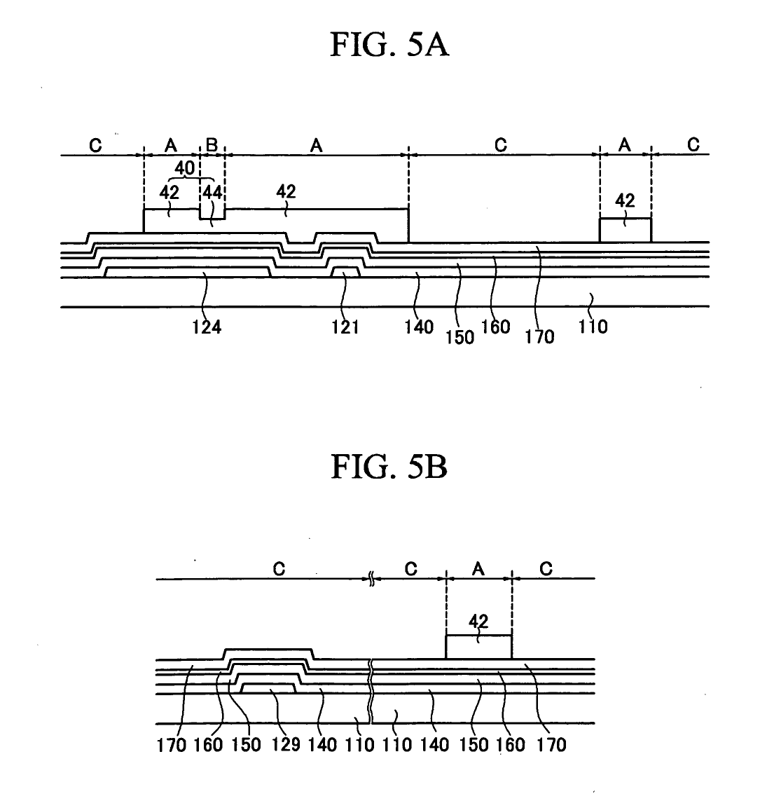

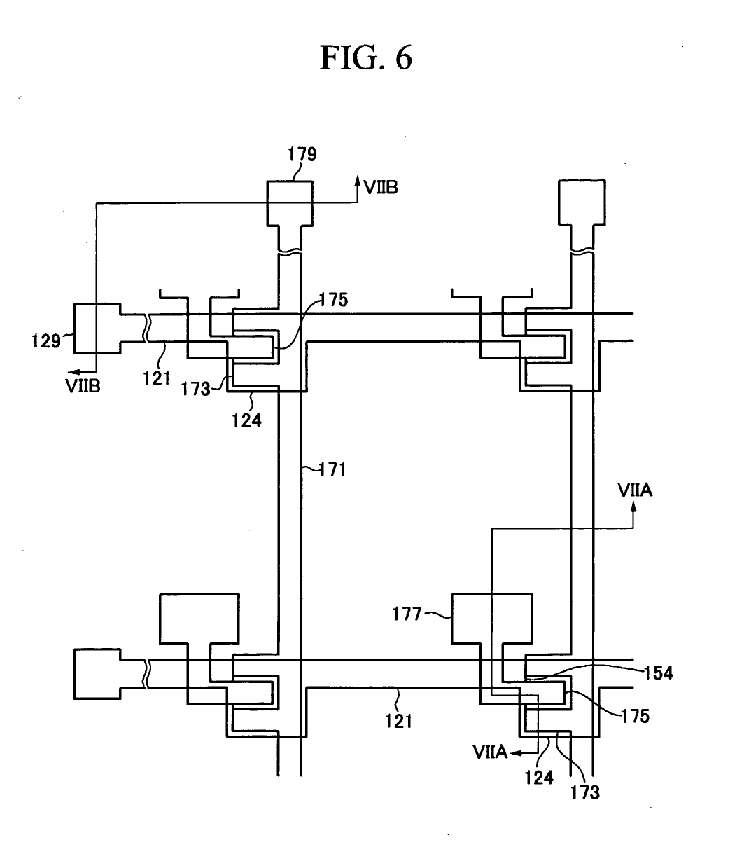

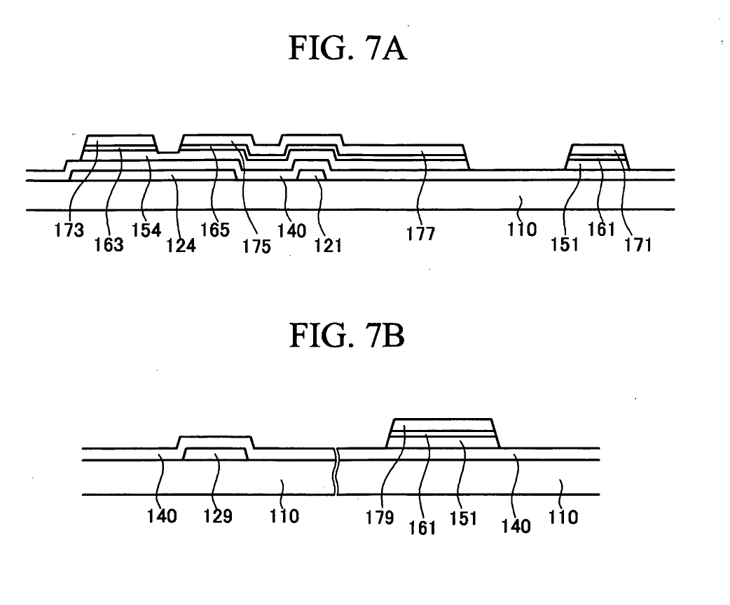

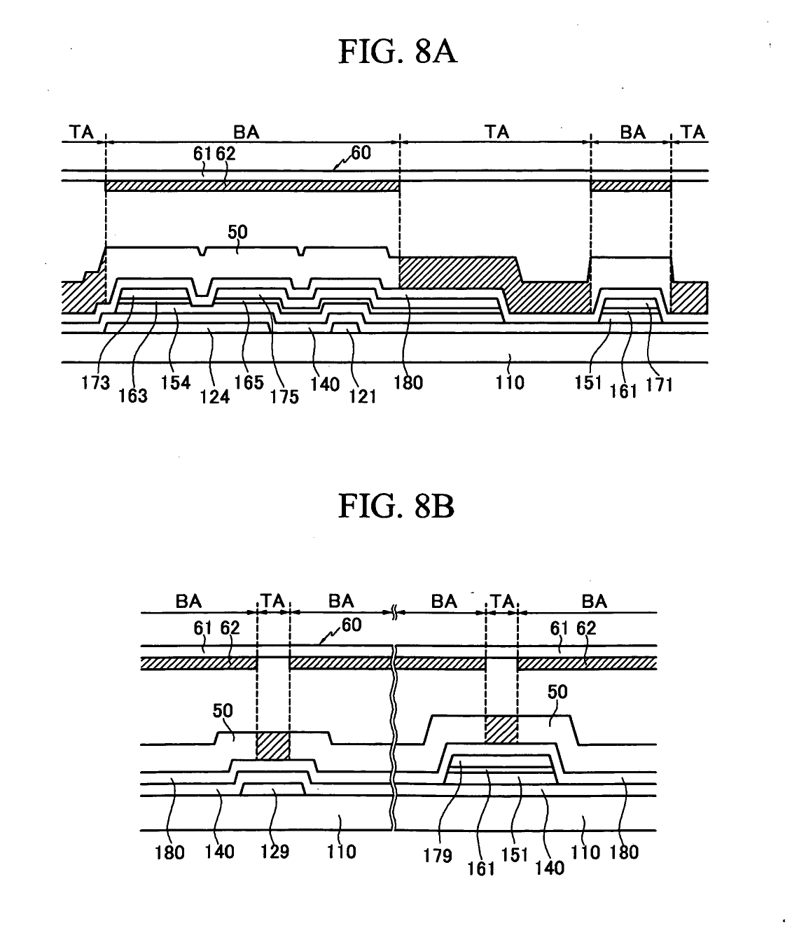

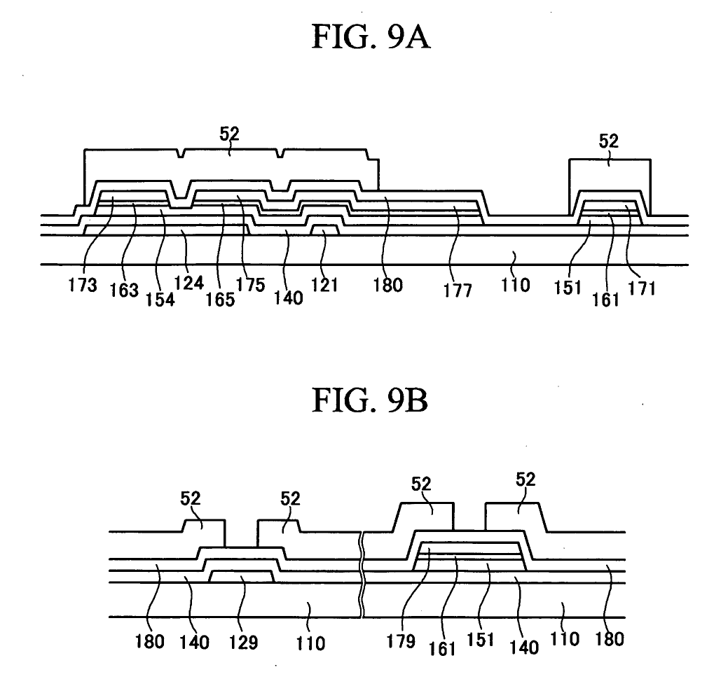

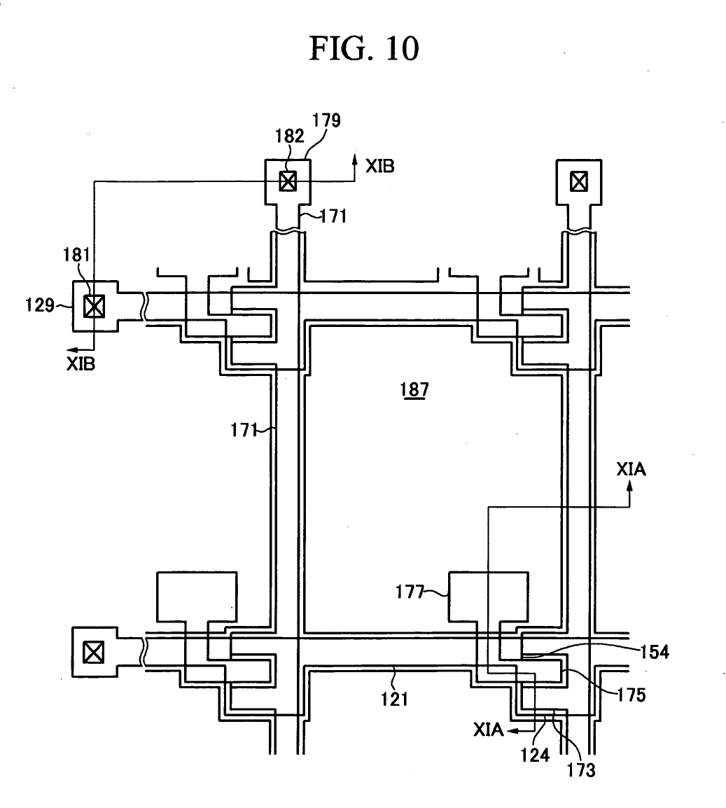

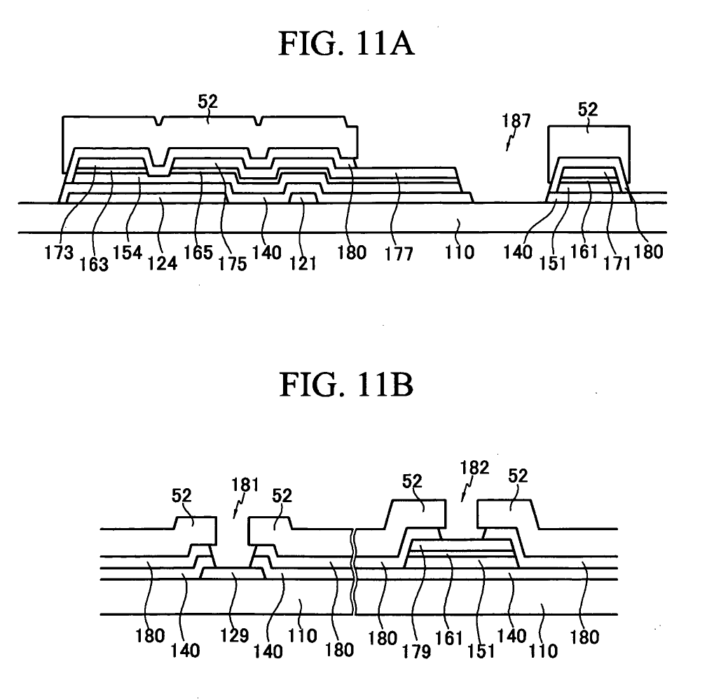

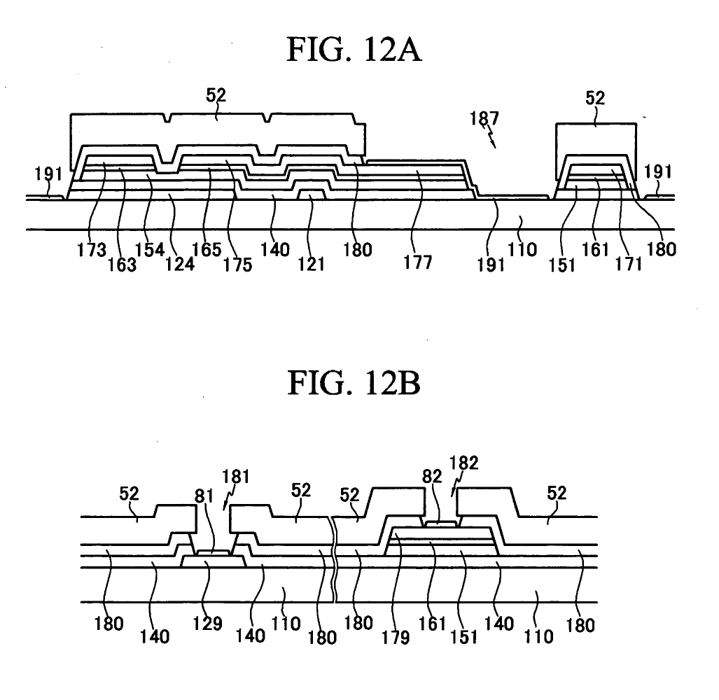

FIGS. 3, 6, and 9 are layout views of a TFT array panel shown in FIGS. 1-2B in intermediate steps of a manufacturing method thereof according to an embodiment of the present invention. FIGS. 4A and 4B are sectional views of the TFT array panel shown in FIG. 3 taken along the lines IVA-IVA and IVB-IVB, respectively and FIGS. 5A and 5B illustrate the step following the step shown in FIGS. 4A and 4B. FIG. 7A are sectional views of the TFT array panel shown in FIG. 6 taken along the lines VIIA-VIIA and VIIB-VIIB, respectively, FIGS. 8A and 8B illustrate the step following the step shown in FIGS. 7A and 7B, FIGS. 9A and 9B illustrate the step following the step shown in FIGS. 8A and 8B, FIGS. 11A and 11B are sectional views of the TFT array panel shown in FIG. 10 taken along the lines XIA-XIA and XIB-XIB, respectively, and FIGS. 12A and 12B illustrate the step following the step shown in FIGS. 11A and 11B.

Referring to FIGS. 3, 4A, and 4B, a conductive layer preferably made of metal is deposited by performing a sputtering process, etc., on an insulating substrate 110 preferably made of a transparent glass. The conductive layer may have a thickness of about 1500-5000 Å. The conductive layer is then subjected to lithography and etching to form a plurality of gate lines 121 including gate electrodes 124 and an end portion 129.

Referring to FIGS. 5A and 5B, a gate insulating layer 140, an intrinsic a-Si layer 150, and an extrinsic a-Si layer 160 are sequentially deposited by CVD. A conductive layer 170 preferably made of metal is then deposited by performing a sputtering process, etc., and a photoresist 40 with a thickness of about 1-2 microns is coated on the conductive layer 170.

The photoresist 40 is exposed to light through a photomask (not shown), and developed such that the photoresist has a position-dependent thickness. The photoresist 40 shown in FIGS. 5A and 5B includes a plurality of first to third portions in order of decreasing thickness. The first portions located on wire areas A and the second portions located on channel areas B are indicated by reference numerals 42 and 44, respectively. No reference numeral is assigned to the third portions located on remaining areas C since they have substantially zero thickness so that underlying portions of the conductive layer 170 can be exposed. The thickness ratio of the second portions 44 to the first portions 42 is adjusted depending upon the conditions in subsequent process steps. It is preferable that the thickness of the second portions 44 is equal to or less than half the thickness of the first portions 42, and in particular, equal to or less than 4000 Å.

The position-dependent thickness of the photoresist is obtained by several techniques, which include, for example, providing translucent areas on the exposure mask as well as by providing light transmitting areas and light blocking opaque areas on the exposure mask. The translucent areas may have a slit pattern, a lattice pattern, or have a thin film or films with intermediate transmittances or thickness. When using a slit pattern, it is preferable that the width of the slits or the distance between the slits is smaller than the resolution of the light exposer used for the photolithography. As another example, a reflowable photoresist may be used. For example, when a photoresist pattern made of a reflowable material is formed by using a normal exposure mask with only transparent areas and opaque areas, it is subject to a reflow process whereby the reflowable material flows onto areas not including the photoresist, thereby forming thin portions of photoresist.

The different thicknesses of the photoresist portions 42 and 44 enable selective etching of underlying layers when undergoing certain processes. Therefore, a plurality of data lines 171 including source electrodes 173 and end portions 179, a plurality of drain electrodes 175 and wide end portions 177, as well as a plurality of ohmic contact stripes 161 including projections 163, a plurality of ohmic contact islands 165, and a plurality of semiconductor stripes 151 including projections 154, may be obtained as shown in FIGS. 6, 7A, and 7B by performing a series of etching steps.

For descriptive purposes, portions of the conductive layer 170, the extrinsic a-Si layer 160, and the intrinsic a-Si layer 150 on the wire areas A (of FIGS. 5A and 5C) are referred to as first portions, portions of the conductive layer 170, the extrinsic a-Si layer 160, and the intrinsic a-Si layer 150 on the channel areas B (of FIG. 5A) are referred to as second portions, and portions of the conductive layer 170, the extrinsic a-Si layer 160, and the intrinsic a-Si layer 150 on the remaining areas C (of FIGS. 5A and 5B) are referred to as third portions.

An exemplary sequence of forming the TFT array panel of FIG. 6 is as follows:

Remove the third portions of the conductive layer 170, the extrinsic a-Si layer 160, and the intrinsic a-Si layer 150 on the wire areas A;

Remove the second portions 44 of the photoresist;

Remove the second portions of the conductive layer 170 and the extrinsic a-Si layer 160 on the channel areas B; and

Remove the first portions 42 of the photoresist.

Another exemplary sequence of forming the TFT array panel of FIG. 6 is as follows:

Remove the third portions of the conductive layer 170;

Remove the second portions 44 of the photoresist;

Remove the third portions of the extrinsic a-Si layer 160 and the intrinsic a-Si layer 150;

Remove the second portions of the conductive layer 170;

Remove the first portions 42 of the photoresist; and

Remove the second portions of the extrinsic a-Si layer 160.

The removal of the second portions 44 of the photoresist is performed either simultaneously with or independent of the removal of the third portions of the extrinsic a-Si layer 160 and the intrinsic a-Si layer 150. Similarly, the removal of the first portions 42 of the photoresist is performed either simultaneously with or independent of the removal of the second portions of the extrinsic a-Si layer 160.

Residue of the photoresist left on the surface of the conductive layer 170 may be removed by performing an ashing process, etc.

Referring to FIGS. 8A and 8B, a passivation layer 180 is deposited and a positive photoresist 50 is coated. Thereafter, a photomask 60 is aligned with the substrate 110. At this time, the surface of the photoresist 50 includes at least one hydrocarbon such as a methyl group (CH₃), and is thereby hydrophobic. One of examples of the photoresist film 50 may be octadecyl trichloro silane (OTS).

The photomask 60 includes a transparent substrate 61 and an opaque light blocking film 62, and it is divided into light transmitting areas TA and light blocking areas BA. The light blocking film 62 is not disposed on the light transmitting areas TA, but it is disposed on the light blocking areas BA.

The light transmitting areas TA face the end portions 129 of gate lines 121, the end portions 179 of data lines 171, and the areas substantially enclosed by gate lines 121 and data lines 171, and the light blocking areas BA face remaining portions 52 and 54 of the photoresist 50. The photoresist 50 is exposed to light through the photomask 60, and it is developed such that portions of the photoresist 50 facing the light blocking areas BA remain as shown in FIGS. 9A and 9B. In FIGS. 8A and 8B, the hatched portions indicate the portions of the photoresist 50 that have been removed after development.

Referring to FIGS. 10, 11A, and 11B, the passivation layer 180 is etched using the remaining portions 52 of the photoresist 50 as an etch mask to form a plurality of contact holes 182 exposing the end portions 179 of data lines 171, upper side walls of a plurality of openings 187 exposing the gate insulating layer 140 of portions of the expansions 177 of the drain electrodes 175 of areas substantially enclosed by gate lines 121 and data lines 171, and upper side walls of the contact holes 181 exposing the gate insulating layer 140 of the end portions of gate lines 121. At this time, it is preferable that the etching is operated without removal of the remaining portions 52 and that the passivation layer 180 is undercut under the remaining portions 52. Furthermore, the passivation layer 180 may not be perfectly removed such that some portions of the passivation layer 180 may remain. On the contrary, portions of the gate insulating layer 140 may be etched along with the passivation layer 180 such that the gate insulating layer 140 may have a reduced thickness. Next, the exposed gate insulating layer 140 is etched using the remaining portions 52 of the photoresist 50 as an etch mask to complete a plurality of contact holes 181 and the openings 187.

Referring to FIGS. 12A and 12B, using the selective deposition, IZO, ITO, or amorphous ITO is deposited on portions on which the photoresist portions 52 are removed, to form a plurality of pixel electrodes 191 and a plurality of contact assistants 81 and 82. When IZO is used, IDIXO (indium x-metal oxide) (manufactured by Idemitsu Co. of Japan) may be used as a target material. The IZO may preferably include In₂O₂ and ZnO, and the amount of Zn in the total amount of indium and Zn may preferably be about 15 to 20 atomic %. The temperature of the sputtering is preferably about 250° C. or less, to minimize contact resistance to other conductive layers.

At this time, the pixel electrodes 191 and the contact assistants 81 and 82 are formed by MOCVD that the IZO, the ITO, or the a-ITO is not deposited on portions including the methyl group (CH₃), and it is preferable that the MOCVD is performed under a predetermined temperature or less, at which characteristics of the photoresist portions 52 of an organic material is varied by oxidating, or processing conditions are changed due to foreign elements generated in oxidating. For example, the predetermined temperature is about 130° C. In addition, it is preferable that the MOCVD is performed under a pressure of about 0.5 mTorr or less.

Alternatively, the pixel electrodes 191 and the contact assistants 81 and 82 may be formed by ELP. In forming pixel electrodes 191 and the contact assistants 81 and 82, when the surface of the photoresist portions 52 is hydrophilic, a surface treating of the photoresist portions 52 is subjected to OTS, etc., such that the surface of the photoresist portions 52 become hydrophobic. Thereby, pixel electrodes 191 ad the contact assistants 81 and 82 are not deposited on the photoresist portions 52.

The substrate 110 is then dipped into the developer such that the developer infiltrates into the photoresist portions 52 through the exposed lateral sides of the photoresist portions 52 to remove the photoresist portions 52 (see FIGS. 1, 2A, and 2B).

Alternatively, portions of the passivation layer 180 near edges of the expansions 177 of the drain electrodes 175 may be left by using a photomask including translucent areas as well at the transmitting areas and the blocking areas. The translucent areas may be of a slit type in which a width or an interval of the light blocking film is less than a predetermined value. At this time, the translucent areas face the portions near the edges of the expansions 177 of the drain electrodes 175.

That is, similarly as shown in FIGS. 8A and 8B, after deposition of the passivation layer 180 on the data lines 171 and the drain electrodes 175, a photoresist is coated, and then a photomask including light transmitting areas, translucent areas, and blocking areas is aligned over the photoresist. The transmitting areas face the end portions 129 of the gate lines 121, the end portions 179 of the data lines 171, and the areas substantially enclosed by the gate lines 121 and the data lines 171, the translucent arreas face near edges of the expansions 177 of the drain electrodes 175, and the light blocking areas face remaining portions.

The photoresist is exposed to light through the photomask, and it is developed such that first phtoresist portions and second photoresist portions thinner than the first photoresist portions are remained. That is, the first photoresist portions correspond to the light blocking areas and the second photoresist portions correspond to the translucent areas.

Next, the exposed passivation layer 180 and the underlying gate insulating layer 140 are sequencially etched by using the first and second phtoresist portions as a mask, and then the second photoresist portions are removed by the ashing process, etc. such that the passivation layer 180 is remained near the edges of the expansions 177 of the drain electrodes 175.

At this time, the thickness of the first photoresist portions is reduced.

Next, similarly as shown in FIGS. 12A and 12B, by using the selective deposition or the ELP, IZO, ITO, or amorphous ITO is deposited on portions on which the second photoresist portions are removed, to form a plurality of pixel electrodes 191 and a plurality of contact assistants 81 and 82. Next, the remaining first photoresist portions are removed.

Thereby, the portions near the edges of the expansions 177 are covered by the passivation layer 180, the undercut under the drain electrodes 175 does not occur, and the disconnection between pixel electrodes 191 and the drain electrodes 175 is prevented.

As described above, pixel electrodes 191 and the contact assistants 81 and 82 are formed on the portions where the photoresist portions 52 are removed using the selective deposition. Thereby a separate photo mask for forming the pixel electrodes is not necessary, which reduces manufacturing processes and manufacturing cost.

According to the present invention, the pixel electrodes and the openings for connecting the drain electrodes and the pixel electrodes are simultaneously formed, and a separate photolithography step is omitted to reduce the total number of manufacture processes and manufacturing cost.

Moreover, a disconnection of the pixel electrodes and the drain electrodes by over-etching of the gate insulating layer under the drain electrodes is prevented, to improve reliability.

Furthermore, the pixel electrodes and the contact assistants are formed by the selective deposition, to reduce the manufacturing cost and the number of manufacturing processes, and thereby to increase productivity.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A manufacturing a thin film transistor array panel, comprising:
forming a gate line comprising a gate electrode on a substrate;
forming a first insulating layer on the gate line;
forming a semiconductor layer on the first insulating layer;
forming an ohmic contact on the semiconductor layer;
forming a data line comprising a source electrode and a drain electrode on the ohmic contact;
depositing a second insulating layer;
forming a first photoresist on the second insulating layer;
etching the second insulating layer and the first insulating layer using the first photoresist as an etching mask to expose a portion of the drain electrode and a portion of the substrate;
forming a pixel electrode connected to an exposed portion of the drain electrode using selective deposition; and
removing the first photoresist.

2. The method of claim 1, wherein the selective deposition is MOCVD (metal organic chemical vapor deposition).

3. The method of claim 2, wherein the MOCVD is performed under about 130° C. or less.

4. The method of claim 1, wherein the first photoresist is hydrophobic.

5. The method of claim 4, wherein the first photoresist comprises at least one hydrocarbon.

6. The method of claim 5, wherein the first phtoresist is oc tadecyl trichloro silane (OTS).

7. The method of claim 1, wherein the first phtoresist is hydrophilic.

8. The method of claim 7, further comprising treating the surface of the first photoresist to make the surface of the first photoresist hydrophobic.

9. The method of claim 8, wherein the surface of the first photoresist is treated by octadecyl trichloro silane (OTS).

10. The method of claim 1, wherein the portion of the drain electrode and the portion of the substrate are included in an area enclosed by the gate and data lines.

11. The method of claim 1, wherein the exposure of the drain electrode and the substrate comprises exposing a portion of the data line and a portion of the gate line.

12. The method of claim 1, wherein the first photoresist is formed by a photo mask comprising a light blocking area and a light transmitting area.

13. The method of claim 1, wherein the first photoresist is formed by a photo mask comprising a light blocking area, a light transmitting area, and a translucent area.

14. The method of claim 13, further comprising forming a second photoresist by changing the first photoresist.

15. The method of claim 13, wherein the drain electrode comprises an expansion, and the translucent area faces near an edge of the expansion.

16. The method of claim 1, wherein the formation of the semiconductor layer and the formation of the data line and the drain electrode comprise:
sequentially depositing a gate insulating layer, an intrinsic amorphous silicon layer, an extrinsic amorphous silicon layer, and a data conductive layer on the gate line;
forming a second photoresist having position-dependent thickness on the data conductive layer; and
selectively etching the data conductive layer, the extrinsic amorphous silicon layer, and the intrinsic amorphous silicon layer using the second photoresist as a mask to form the data line, the drain electrode, and the ohmic contact.

17. The method of claim 16, wherein the second photoresist is formed by a photo mask comprising a light blocking area, a translucent area, and a light transmitting area.
